(19) United States
(12) Patent Application Publication
(10) Pub. No.: US 2005/0021252 A1
(43) Pub. Date: Jan. 27, 2005

(54) Power protector controllable via internet

(75) Inventor: Kwok-Ying Hui, New Territories (HK)

Correspondence Address: ARENT FOX KINTNER PLOTKIN & KAHN, PLLC;Suite 400, 1050 Connecticut Avenue, N.W., Washington, DC, 20036-5339, US

(73) Assignee: Rocom Electric Company Ltd.

(21) Appl. No.: 10/862,410

(22) Filed: Jun. 8, 2004

(30) Foreign Application Priority Data
Jul. 21, 2003 (TW) 92213291

(51) Int. Cl. G01R 21/00

(52) U.S. Cl. 702/60

(57) ABSTRACT

A power protector is controllable via the Internet. In a web, the power protector receives control commands from a remote control server, responds to the control commands and control the operation of a system based on configuration parameters. The power protector includes a microprocessor control circuit for receiving control commands from a terminal of the web, an I/O control circuit under control of the microprocessor control circuit, a power monitor circuit for monitoring the voltage and current of the power network and sending responses to the microprocessor control circuit, and a ground monitor circuit for monitoring the connection status of the ground of the power network.

### BACKGROUND OF THE INVENTION

1. Field of the Invention

The present invention relates to a power protector with an Internet Protocol (“IP”) address so that it is controllable via the Internet and, more particularly, to a power protector that receives control commands from a remote control server in a web. The power protector includes an I/O control circuit for responding to the control commands and a power monitor circuit for monitoring the operation status of a system based on configuration parameters.

2. Description of the Related Art

Conventionally, a power protector is used to protect a circuit or device. When a failure occurs in a portion (“malfunctioning portion”) of the circuit or device, the power protector isolates the malfunctioning portion from the remaining portion (“normal portion”) of the circuit or device. Thus, the failure will not affect the formal portion. The malfunctioning portion should be limited to a minimum scope in order to provide an optimum power supply quality. To this end, the operation of the power supply must be regulated. Otherwise, when a failure occurs in a system, power protectors that should not be actuated are actuated so that a power cut is conducted in a scope larger than necessary, or power protectors that should be actuated are not actuated so that related equipment are burnt and/or nearby personnel is hurt.

A power network includes two or more power protectors. When a failure occurs in the power network, an unusual electric current flows from a power supply to a malfunctioning point. The power supply near the malfunctioning point rapidly isolate the malfunctioning point from the power network so as to protect the power network. Hence, all important power devices are equipped with power protectors in order to promote the protection of the power devices.

The conventional power protector cannot monitor and indicate the connection of a ground so that leakage can occur easily. Because of different allowed scopes of fluctuations of voltage in different electric devices, conventional power protectors cannot modify and set responses to abnormal voltages that call for alerts and overload currents. Because of operation in overload, fractional devices might last shorter than they are designed to or be damaged. In addition, the conventional power protector requires an individual web and includes a limited control distance. For example, the control distance cannot exceed 1500 meters with RS485 or 10 kilometers with CAN.

Therefore, a power protector controllable via the Internet is needed. With such a power protector, a user controls a remote power supply and device through the Internet so that the power protector responds to a control command and controls the operation of a system according to configuration parameters.

### SUMMARY OF THE INVENTION

It is an objective of the present invention to provide a power protector with an IP address so as to be controllable via the Internet in order to monitor the connection of a ground and indicate the connection status of the ground by means of an LED so as to prevent leakage.

It is another objective of the present invention to provide a power protector with an IP address so as to be controllable via the Internet in order to enable a user to modify and set the bonds of voltages and responses so that devices that allow different voltage fluctuation ranges are operable in their individual voltage fluctuation ranges.

It is another objective of the present invention to provide a power protector with an IP address so as to be controllable via the Internet in order to enable a user to modify and set the bonds of currents and responses so as to monitor and respond to overload operation of devices of different powers in order to prevent reduced lifecycles and damages of the devices because of overload operation.

It is another objective of the present invention to provide a power protector with an IP address so as to be controllable via the Internet in order to receive control commands on the Internet without the need of an individual web and without limit in the control distance.

According to the present invention, a power protector is controllable via the Internet and connected with a power network. The power protector comprises a web controller comprising an IP address for connection with a web, a microprocessor control circuit for receiving control commands from a terminal of the web, an I/O control circuit connected with the power supply of the power network under control of the microprocessor control circuit, and a ground monitor circuit for monitoring the connection status of the ground of the power network.

The microprocessor control circuit uploads the monitoring of the I/O control circuit and the responses of the power monitor circuit to the web.

Other objects, advantages and novel features of the invention will become more apparent from the following detailed description in conjunction with the drawings.

### BRIEF DESCRIPTION OF THE DRAWINGS

The present invention will be described via detailed illustration of the preferred embodiment referring to the drawings.

FIG. 1 is a block diagram of a power protector with an IP address so as to be controllable via the Internet according to the present invention.

FIG. 2 shows a layout of an I/O control circuit of the power protector shown in FIG. 1.

FIG. 3 shows a layout of a power monitor circuit of the power protector shown in FIG. 1.

FIG. 4 is a block diagram of a power protector with an IP address so as to be controllable via the Internet according to the preferred embodiment of the present invention.

### DETAILED DESCRIPTION OF THE PREFERRED EMBODIMENT

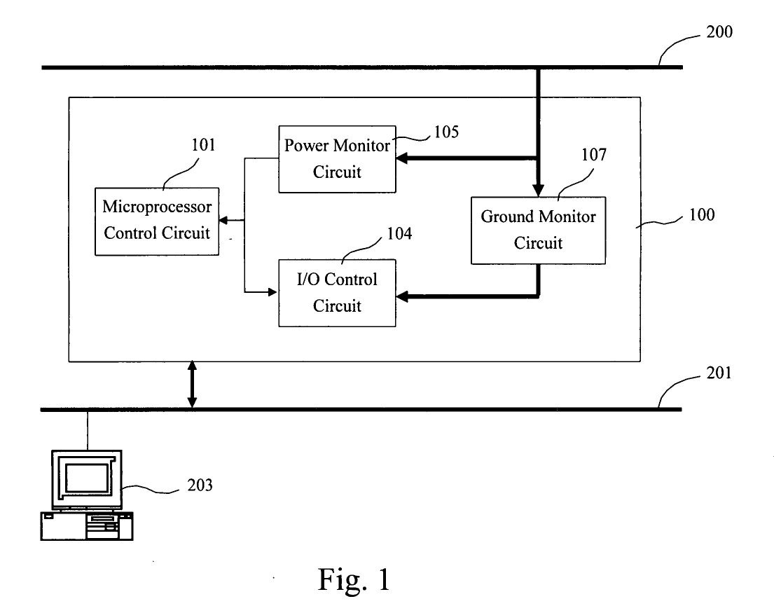

FIG. 1 is a block diagram of a power protector 100 with an IP address so as to be controllable via the Internet according to the present invention. Referring to FIG. 1, the power protector 100 includes a terminal 103 that is a web controller with an IP address and connected with a web, a microprocessor control circuit 101 for receiving control commands from a remote control server 203 through the terminal 103, an I/O control circuit 104 under control of the microprocessor control circuit 101, a power monitor circuit 105 for monitoring the voltage and current in a power network 200 and for sending responses to the microprocessor control circuit 101 and a ground monitor circuit 107 for monitoring the connection status of the ground of the power network 200.

Still referring to FIG. 1, the microprocessor control circuit 101 of the power protector 100 is connected with a web 201 via the terminal 103 so as to receive various control commands or configuration parameters control commands sent to the IP address through the web. The control commands are immediate turning on, immediate turning off, delayed turning on and delayed turning off of a relay for example. The configuration parameters are delay time, upper and lower bonds of voltage and current alerts and the types of responses to alerts for example. The microprocessor control circuit 101 responds to the control commands through the I/O control circuit 104. Based on the configuration parameters, the microprocessor control circuit 101 controls the operation of the system via the power monitor circuit 105.

The power protector 100 monitors the status of the connection of the ground of an electric device with the ground of the power network via the ground monitor circuit 107. When the connection of the grounds is abnormal, a red light is turned so as to indicate a missing ground in order to remind a user of taking responses in order to prevent leakage.

Based on the actual requirements of the electric device, the power protector conducts settings of the upper and lower bonds of voltage and the types of responses to alerts via setting the configuration parameters. The responses are providing audio and optical alerts and turning off a power socket that has been turned on for example. Based on these settings, the microprocessor control circuit 101 monitors and responds to the voltage of the electric device via the power monitor circuit 105 on a real-time basis. Thus, devices that allow different voltage fluctuation ranges are operable in their individual voltage fluctuation range.

Moreover, based on the actual requirements of the electric device, the power protector 100 conducts settings of the upper and lower bonds of current and the types of responses to alerts via setting the configuration parameters. The responses are providing audio and optical alerts and turning off the power socket that has been turned on. Based on these settings, the microprocessor control circuit 101 monitors and responds to the current of the electric device via the power monitor circuit 105 on a real-time basis. Thus, devices are protected from reduced lifecycle and damages because of overload operation.

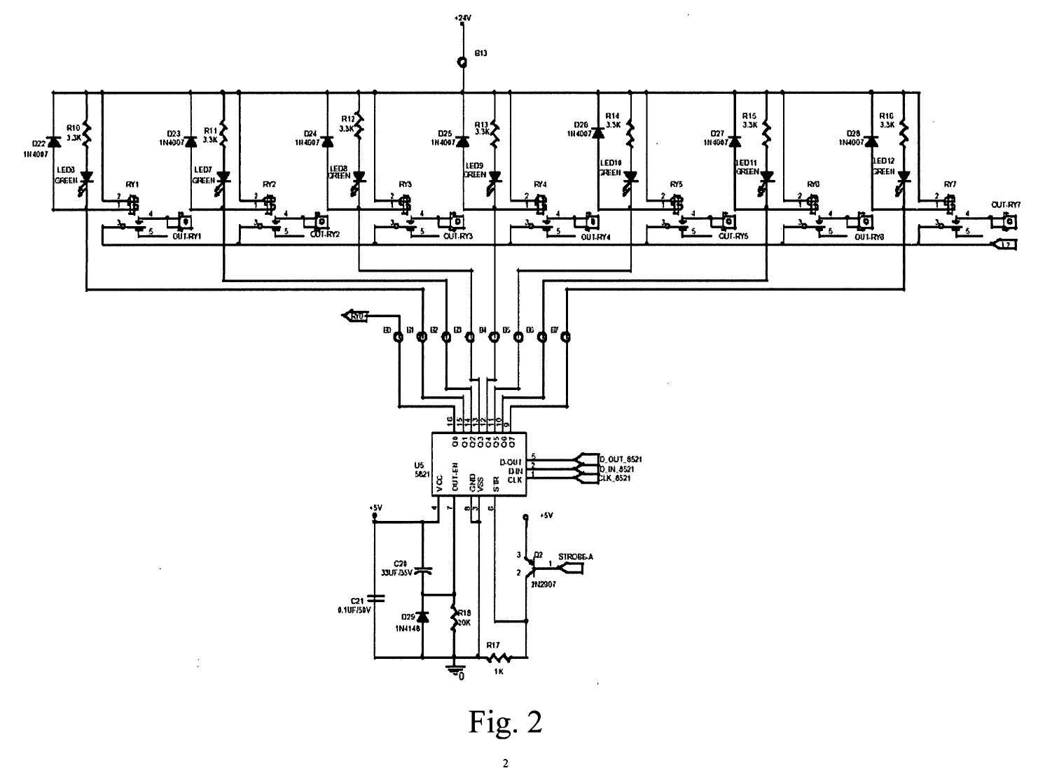

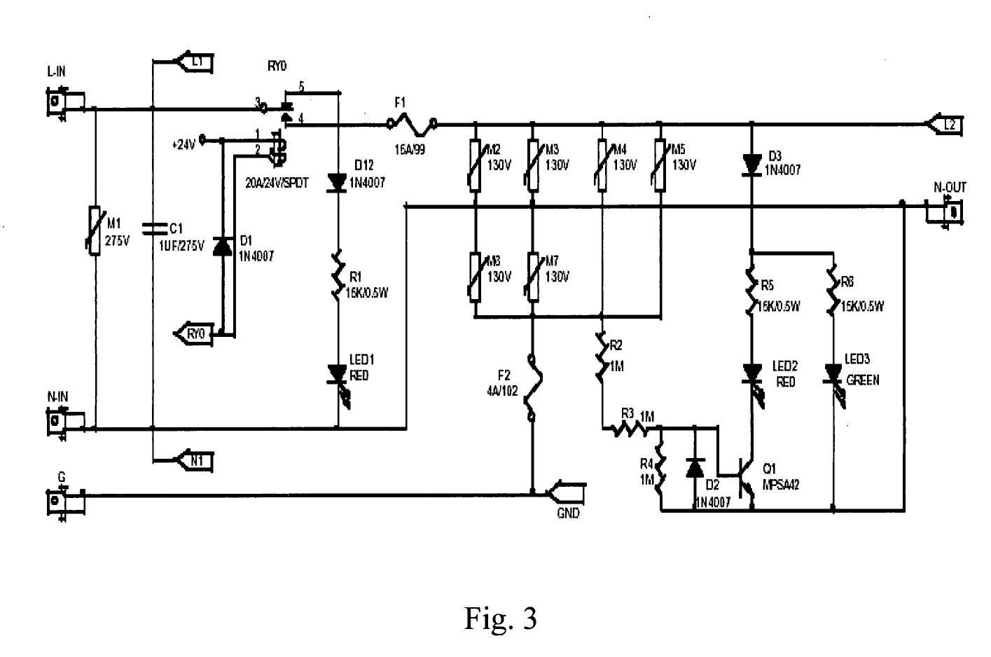

FIG. 2 shows the preferred embodiment of the I/O control circuit, and FIG. 3 shows the preferred embodiment of the power monitor circuit. Referring to FIG. 3, the power monitor circuit includes three LED indicators, i.e., one for indicating unsafe voltage, another for indicating a missing ground and the other for indicating the power connection status. Thus, the monitor status of the ground can be indicated.

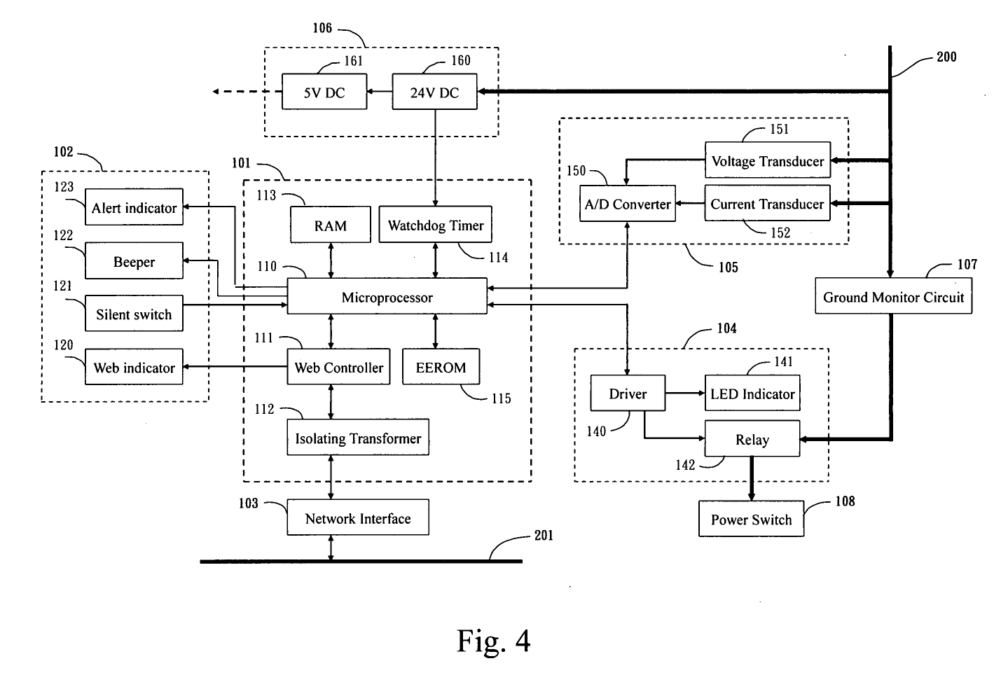

FIG. 4 shows a power protector an IP address so as to be controllable via according to the preferred embodiment of the present invention. Referring to FIG. 4, according to the preferred embodiment of the present invention, the microprocessor control circuit 101 receives the control commands from the terminal 103 in order to monitor and respond to the AC voltage and current based on the configuration parameters and upload the responses and the control messages on a real-time basis. The microprocessor control circuit includes a microprocessor 110 (an 8-bit microprocessor), a web controller 111 (an aether net controller) connected with an isolating transformer 112 for transmit and receive the control commands and monitored status messages, a watchdog timer 114 for avoiding hanging of the system and conducting protection against power failure, a read only memory 115 (Electrically Erasable and Programmable Read Only Memory: EEPROM) for storing system configuration parameters and a memory 113 (random access memory: RAM) for storing various control messages, status messages, data packages and metadata.

The I/O control circuit 104 is an executive mechanism receiving relay messages and action commands from the microprocessor control circuit 101 in order to control a corresponding relay and LED indicator so as take corresponding actions. The control circuit 104 includes an 8-bit serial-input, parallel-output driver 140 with a latch for directly driving a relay 142 and LED indicator 141. At least one relay 142 is used to control the on and off of the power supply switch 108.

The power monitor circuit 105 is used to monitor the voltage fluctuation of the power network and the current variations of the electric device and sends the monitored values to the microprocessor control circuit 101 as criteria for use in status monitor by the microprocessor control circuit 101. The power monitor circuit 105 includes an 8-bit serial input and output four-pass A/D converter 150, a voltage transducer 151 for monitoring the voltage fluctuation in the power network and a current transducer 152 for monitoring the current variation in the electric device.

Channel 0 of the A/D converter 150 is used to convert the output current of the current transducer 152, and channel 1 of the A/D converter 150 is used to convert the output voltage of the voltage transducer 151.

The ground monitor circuit 107 is used to monitor the status of the connection the ground of the electric device and the ground of the power network. When the connection is abnormal, the MISSING GROUND indicator (red light) is lit up. When the connection is normal, the POWER NETWORK CONNECTION STATUS indicator (green light) is lit up.

In another embodiment of the present invention, a status indication circuit 102 may be included. When the power protector 100 receives various control commands or configuration parameters of the IP address from the Internet, the I/O control circuit 104 responds to the control commands, and the power monitor circuit 105 monitors the system operation status based on the configuration parameters. After corresponding indication is made by means of the status indication circuit 102 connected with the microprocessor control circuit 101, the corresponding monitored messages are up loaded.

The status indication circuit 102 includes an alert indicator 123, a beeper 122, a silent switch 121 or web indicator 120.

The present invention has been described via detailed illustration of the preferred embodiment. Those skilled in the art can derive variations from the preferred embodiment without departing from the scope of the present invention. Therefore, the preferred embodiment shall not limit the scope of the present invention defined in the claims.

1. A power protector controllable via an Internet, connected with a power network, the power protector comprising:
a web controller having an IP address for connecting with a web;
a microprocessor control circuit for receiving control commands from a terminal of the web;
an I/O control circuit connected with a power supply of the power network under control of the microprocessor control circuit;
a power monitor circuit for monitoring the voltage and current of the power network and sending responses to the microprocessor control circuit; and
a ground monitor circuit for monitoring the connection status of the ground of the power network;
wherein the microprocessor control circuit uploads the controlling status of the I/O control circuit and the responses of the power monitor circuit to the web.

2. The power protector according to claim 1 wherein the web controller is a network card.

3. The power protector according to claim 1 further comprising a status indication circuit.

4. A power protector controllable via an Internet, connected with a power network, the power protector comprising:
a terminal having an IP address for connecting with a web;
an I/O control circuit connected with the power network for providing power from the power network in response to a control command;
a ground monitor circuit for monitoring the connection status of the ground of the power network; and
a microprocessor control circuit for transmitting the control command to the I/O control circuit from the terminal and upload the control status of the I/O control circuit and the connection status of the ground of the power network onto the web.
